(19) United States
(12) Patent Application Publication
(10) Pub. No.: US 2016/0056803 A1
(43) Pub. Date: Feb. 25, 2016

(54) APPARATUS AND METHOD FOR GENERATING HIGH-VOLTAGE PULSES

(71) Applicant: SIEMENS AKTIENGESLLSCHAFT, München (DE)

(72) Inventors: Werner HARTMANN, Weisendorf (DE); Martin HERGT, Nuremberg (DE)

(73) Assignee: SIEMENS AKTIENGESELLSCHAFT, Munich (DE)

(21) Appl. No.: 14/784,811

(22) PCT Filed: Apr. 8, 2014
(86) PCT No.: PCT/EP2014/057009

§ 371 Date: Oct. 15, 2015

(30) Foreign Application Priority Data
Apr. 18, 2013 (DE) 10 2013 207 020.9

(51) Int. Cl. H03K 3/53; H01P 3/06

(52) U.S. Cl. CPC H03K 3/53; H01P 3/06

(57) ABSTRACT

An apparatus and a method for generating high-voltage pulses using an inductive voltage adder, in which a first stage contains an electromagnetically coupling funnel-shaped intermediate piece positioned between a radial transmission line and a coaxial transmission line for transmitting electromagnetic waves from the radial transmission line into the coaxial transmission line.

### CROSS-REFERENCE TO RELATED APPLICATIONS

This application is based on and hereby claims priority to International Application No. PCT/EP2014/057009 filed on Apr. 8, 2014 and German Application No. 10 2013 207 020.9 filed on Apr. 18, 2013, both applications are incorporated by reference herein in their entirety.

### BACKGROUND

1. Field

Described below are an apparatus and a method for generating high-voltage pulses.

2. Description of the Related Art

In electrical engineering, high-voltage pulses and high-power pulses with amplitudes of a few kW to several hundred TW are used for scientific and industrial purposes in the field of pulsed power technology, with pulse durations being in the ps to ms range.

A pulse generator which can generate voltages of 250 kV and currents of a few 10 kA with a pulse duration of 1 μs to 2 μs, for example, is required for so-called electroporation which is mentioned here as an example of an industrial application.

One possible topology for implementing such a pulse generator is a so-called “inductive voltage adder” which is abbreviated using IVA. Such a generator enables a compact structure since the generator is composed as a series circuit of n discrete voltage sources during pulse generation. The electromagnetic fields are physically combined in the IVA in a conductor geometry called a transformer.

“Pulsed Power Systems Principles and Applications”, Hansjochim Bluhm, Springer Verlag Berlin Heidelberg, 2006 discloses the structure and methods of operation of IVAs, in particular in chapter 7, pages 192-201.

In this manner, the transformer substantially determines the design of an IVA (inductive voltage adder). A suitable design of the individual transformer stages makes it possible to obtain a modular design for optimizing the size of the IVA. In particular, it is necessary for the individual successive stages to be electrically matched to one another in an optimum manner, with the result that there are no reflections of the electrical signals between the stages which would call into question the method of operation of the IVA. This applies, in particular, to the first and second stages since, in the known coaxial arrangement which is usually used, the first stage cannot be geometrically identical to the second stage since the second stage itself does not have an input side.

An IVA makes it possible to use the wave properties to increase the current amplitude during the switch-on process and in the steady state owing to the reflection factors. FIG. 1 shows the known principle of an IVA. FIG. 1 shows the basic principle of the IVA using the example of four stages. In a similar manner to that in the case of a serial arrangement of voltage sources which are illustrated on the left-hand side in FIG. 1, pulse lines, as are illustrated on the right-hand side of FIG. 1, can be implemented in the form of voltage multiplier circuits by connecting the positive conductor of one line to the negative conductor of the other line. So that no short circuit is produced with this alternating connection of the conductors, the connection must be insulated for the duration of the pulse. This can be achieved with the aid of sufficiently long transmission lines in the form of a cable transformer, or by coupling to sufficiently high coupling inductances according to the embodiment of an IVA. A more compact structure is possible if inductive insulation is used instead of the propagation time when adding the pulse lines of individual stages. The principle of voltage addition using magnetic insulation according to the IVA is illustrated in FIG. 2.

FIG. 2 shows a known exemplary embodiment of an IVA with magnetic insulation. FIG. 2 shows six stages which are arranged in a coaxial manner. Reference symbol 1 denotes a vacuum interface, reference symbol 3 denotes a vacuum, reference symbol 5 denotes an annular gap, reference symbol 7 denotes a magnetic core, reference symbol 9 denotes a diode and reference symbol 11 denotes oil. The cylindrical cavities form an inner conductor of the IVA and are radially fed by known voltage sources Ux arranged in a coaxial manner. In the case of the applications described, each of the individual cavities provides a pulse with a duration of 0.1 to 50 μs, for example, with a voltage amplitude U0 of a few kV, for example in the range of 1 to 10 kV, and a maximum current amplitude 10 of a few kA to >10 kA. In order to add the voltage amplitudes, vector addition of the electromagnetic fields in the transition region to the coaxial transmission line is used. The IVA therefore generates a voltage pulse which is superimposed from the sum of the n (n: number of stages) individual voltage sources. Accordingly, an arrangement according to FIG. 2 generates a sextuple voltage pulse. In order to add the voltage amplitudes, the positive conductor of one voltage source is connected to the negative conductor of the following voltage source. This inevitably produces a conductive connection between the central electrode and the outer electrode remote from the current in each cavity. In order to prevent a short circuit from being produced in the output of the line in this manner, the impedance of the connection is greatly increased by increasing the relative permeability in this section. For this purpose, a partial volume of the voltage source is filled with toroidal cores made of ferromagnetic material.

FIG. 3 shows a known exemplary embodiment of a first stage. FIG. 3 shows a section of a known simulation model which is rotationally symmetrical about a wave propagation main axis HA. In this case, a signal is fed into a connection 13 (or port) and is forwarded to a connection 15. Guidance is effected along a hollow cylindrical channel 18 of a radial transmission line 19 into a hollow cylindrical channel 20 of a coaxial line or a coaxial transmission line 21 and along the latter. The channels 18 and 20 are bounded and created using walls which have an electrically conductive material 22.

The upper curve of FIG. 4 shows the temporal profile of a feed signal E, the central curve of FIG. 4 shows the temporal profile of the reflected signal component R of the feed signal and the lower signal profile shows the transmitted signal components T. With such a structure, the pulse generation modules (not shown) are characterized as a connection 13. This geometry has the advantage that it is geometrically largely identical to the subsequent stages. However, it can be gathered from the simulation results, in particular according to FIG. 4, that the first coupling or transformer stage has considerable reflections of the input signal, which in reality would result in a severely higher input power in order to provide the necessary output power at the connection 15. Therefore, such a known solution is technically very unfavorable since the connection 13 modules must electrically differ greatly from the modules used in the subsequent stages.

A first stage of a known IVA is therefore usually implemented using a coaxial feed, as a result of which the first stage differs considerably, geometrically and electrically, from the subsequent stages. The complexity of the arrangement and therefore also its costs are therefore high in the known solutions.

### SUMMARY

Therefore, in one aspect, a suitable geometrical arrangement of a first stage of an inductive voltage adder (IVA) is described which can be implemented using the same submodules which are used in the subsequent stages to generate pulses. A corresponding pulse-matching method is also described.

In one aspect, an apparatus for generating high-voltage pulses, in particular an inductive voltage adder, is described in which, during pulse generation, electromagnetic fields of a series circuit of a plurality of discrete stages of voltage sources which are arranged along a wave propagation main axis are combined in a transformer, wherein, in each stage, waves respectively propagate along a radial transmission line having a first characteristic impedance into a coaxial transmission line having a second characteristic impedance and, in contrast to the subsequent stages, a steady and continuous transition from the first characteristic impedance to the second characteristic impedance is created in the first stage using a steady and continuous transition region from the radial transmission line to the coaxial transmission line.

In a second aspect, a method for generating high-voltage pulses, in particular by an inductive voltage adder, is described in which, during pulse generation, electromagnetic fields of a series circuit of a plurality of discrete stages of voltage sources which are arranged along a wave propagation main axis are combined in a transformer, wherein, in each stage, waves respectively propagate along a radial transmission line having a first characteristic impedance into a coaxial transmission line having a second characteristic impedance and, in contrast to the subsequent stages, a steady and continuous transition from the first characteristic impedance to the second characteristic impedance is created in the first stage using a steady and continuous transition region from the radial transmission line to the coaxial transmission line.

A pulse generator is described which can be configured as compactly and cost-effectively as possible. In one embodiment, a geometry of the first transformer stage is described that it possible to select all matching networks, switches, capacitors and driver circuits in a modular manner with respect to all other transformer stages. This now enables a modular structure between the first transformer stage and the subsequent transformer stages. A modular design of an IVA reduces the costs and simultaneously enables a more compact design. In one embodiment, a first transformer stage of the IVA is described in which the electromagnetic wave is transmitted to a coaxial transmission line via a radial transmission line. These two lines are connected to one another by a funnel-shaped intermediate piece (taper). The proposed embodiment of a first stage of an IVA is used to feed the power into the first stage without reflection. A radial arrangement, as in the subsequent stages, is likewise obtained here in the region in which the pulse generation modules (first connection 13) are coupled. On account of the reflection-free coupling to the second stage, work can be carried out in the first stage using the same electrical power as in the subsequent stages. This also makes it possible to use the same modules in the first stage as in all subsequent stages, which considerably reduces the complexity, reliability and costs of such an installation. This makes it possible to optimize the modularity and construction volume of the overall system. Furthermore, the overall costs for such a system can be effectively reduced.

According to another aspect, the continuous transition in the first stage can be created using the first characteristic impedance of the radial transmission line and an inner radius and an outer radius of the coaxial transmission line as well as a field characteristic impedance.

According to another aspect, in the transition region of the first stage, walls of the radial transmission line which extend transversely with respect to the wave propagation main axis may continuously merge into walls of the coaxial transmission line which extend longitudinally with respect to the wave propagation main axis along winding profiles in a rotationally symmetrical manner with respect to the wave propagation main axis.

According to another aspect, a first spatial material extent can be created in the transition region of the first stage, the material extent having circular cross-sectional areas which are perpendicular to the wave propagation main axis HA and the radii of which are produced in a diminishing manner such that they fall continuously starting from the outer radius of the outer conductor to the outer radius of the inner conductor of the coaxial transmission line along and in the direction of the direction of the wave propagation main axis. A spatial material extent is, in particular, a general three-dimensional physical body or region of such a body having a material.

In this case, “along and in the direction of the direction of the wave propagation main axis (HA)” means “along the wave propagation main axis (HA) and in the direction of the direction of the wave propagation main axis (HA)” and, in particular, “running parallel to the wave propagation main axis, to be precise in the direction in which the wave propagation main axis points”. This direction is the direction in which the waves mainly propagate.

According to another aspect, a second spatial material extent can be created in the transition region Ü of the first stage, the material extent having circular cross-sectional areas which are perpendicular to the wave propagation main axis and the outer radii of which are produced in a constant manner and the inner radii of which are produced in a diminishing manner such that they fall continuously starting from the outer radius to the inner radius of the outer conductor of the coaxial transmission line along and in the direction of the direction of the wave propagation main axis.

According to another aspect, the radii of the cross-sectional areas of the first spatial material extent and/or the inner radii of the cross-sectional areas of the second spatial material extent may be produced in a diminishing manner such that they fall exponentially starting from the side of the radial transmission line in the direction of the side of the coaxial transmission line.

According to another aspect, the radius profiles of the radii of the cross-sectional areas of the first spatial material extent and of the inner radii of the cross-sectional areas of the second spatial material extent may be produced in a manner running parallel to one another starting from the side of the radial transmission line in the direction of the side of the coaxial transmission line.

According to another aspect, the first spatial material extent may be created as a solid separate intermediate piece.

According to another aspect, the intermediate piece may have an outer surface profile of a solid, in particular radially tapering, funnel shape along and in the direction of the direction of the wave propagation main axis.

According to another aspect, the first and second spatial material extents may have the same material, in particular copper, steel or aluminum.

According to another aspect, all n stages may have the same modular structure with respect to their electrotechnical connection or their electrical connections.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 is a plan view of a known exemplary embodiment of an IVA;

FIG. 2 is a plan view of a known exemplary embodiment of an IVA;

FIG. 3 is a section view of a known exemplary embodiment of a first transformer stage of an IVA;

FIG. 4 is a graph illustrating a simulation of the known exemplary embodiment of the first transformer stage;

FIG. 5 is a section view of an exemplary embodiment of a first transformer stage of an IVA;

FIG. 6 is a graph of the signal profiles for the exemplary embodiment of a first transformer stage of an IVA;

FIG. 7 is an illustration of the electrical fields of a first stage of an IVA;

FIG. 8 is an illustration of magnetic fields of the exemplary embodiment of a first stage of an IVA;

FIG. 9 is a further illustration of the exemplary embodiment of a first stage of an IVA.

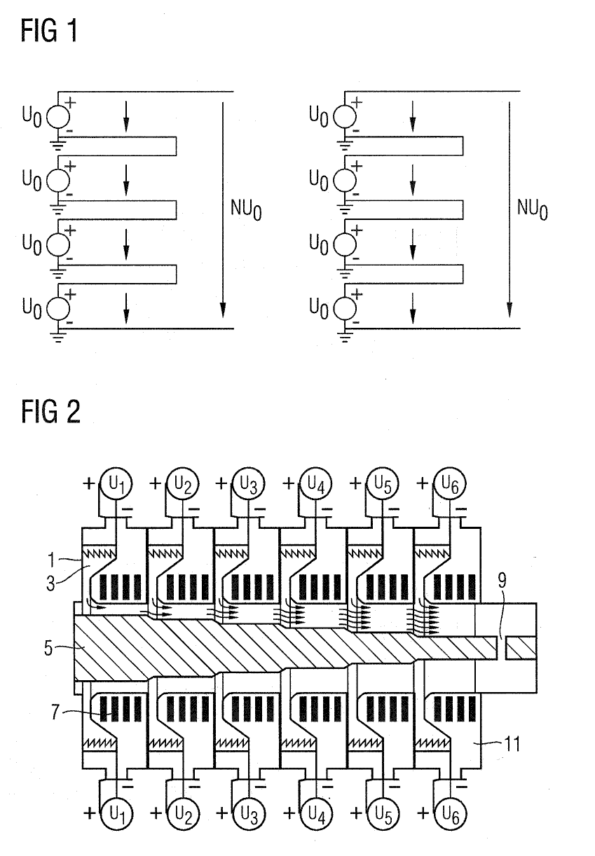

### DETAILED DESCRIPTION OF THE PREFERRED EMBODIMENTS

Reference will now be made in detail to the preferred embodiments of the present invention, examples of which are illustrated in the accompanying drawings, wherein like reference numerals refer to like elements throughout.

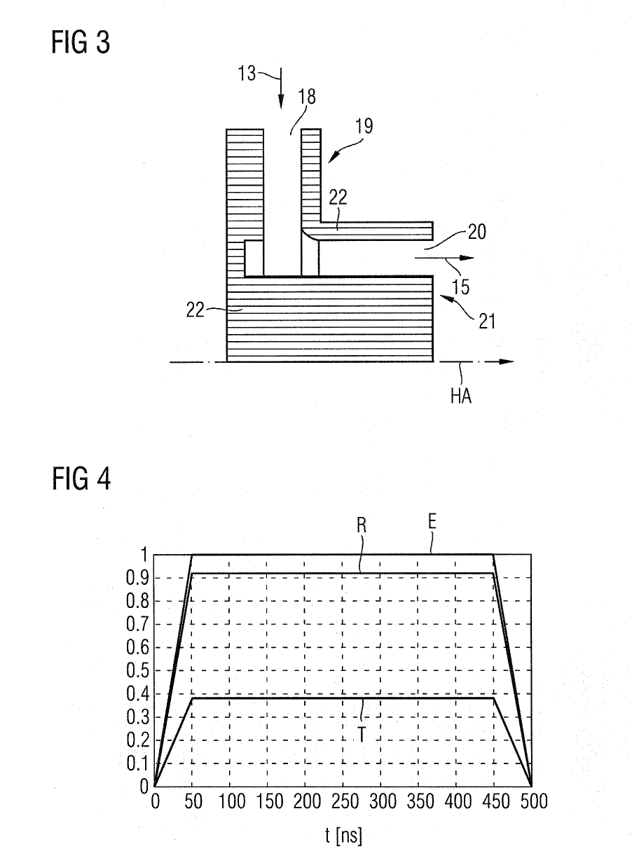

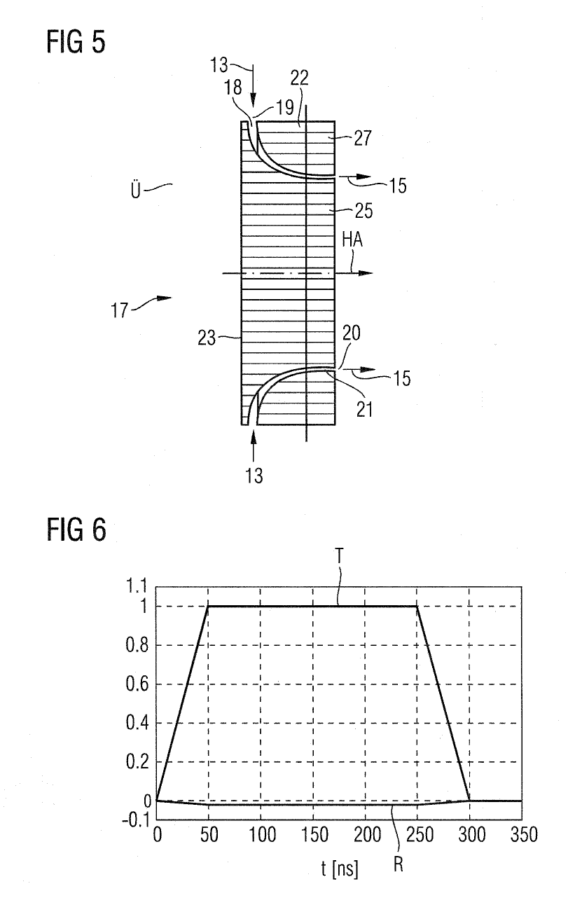

FIG. 5 shows a first exemplary embodiment of a first stage of an IVA (inductive voltage adder), this first stage extending in a rotationally symmetrical manner along a wave propagation main axis HA. In a similar manner to FIG. 3, a signal is fed into a first connection 13 and is forwarded to a second connection 15.

In this first stage 17, the electromagnetic waves are first of all transmitted along a radial transmission line 19 and then along a coaxial transmission line 21. Guidance is effected along the hollow cylindrical transmission line 19, which is vertical in this case, to the hollow cylindrical coaxial line 21 which is horizontal in this case and has an outer conductor 27 on an outer side and an inner conductor 25 on an inner side.

A transition region Ü continuously leads a hollow cylindrical channel 18 of the radial transmission line 19, which extends transversely with respect to the wave propagation main axis HA, homogeneously into a hollow cylindrical channel 20 of the coaxial transmission line 21, which extends along the wave propagation main axis HA, along surfaces of an electrically conductive material 22 which provide curved delimitation along winding profiles.

Along a transition from the radial transmission line 19 to the coaxial transmission line 21, a solid intermediate piece 23 is positioned here. This intermediate piece 23 spatially extends with circular cross-sectional areas in a manner rotationally symmetrical to and along the wave propagation main axis HA from a first outer circular surface having a first radius to a second outer circular surface having a second radius which is smaller than the first radius. In this case, the second radius is equal to the outer radius of the inner conductor 25 and therefore equal to the inner radius of the hollow cylindrical coaxial line 21. A second spatial material extent is created in the transition region Ü between the outer conductor 27, which delimits the hollow cylindrical coaxial line 21 to the outside, and an associated material 22 which makes contact with the outer conductor 27, the material extent having circular cross-sectional areas which are perpendicular to the wave propagation main axis HA and the outer radii of which are produced in a constant manner and the inner radii of which are produced in a diminishing manner such that they fall continuously starting from the outer radius to the inner radius of the outer conductor of the coaxial transmission line 21 along and in the direction of the wave propagation main axis HA. The radii and/or the inner radii of the cross-sectional areas may be produced in a diminishing manner such that they fall exponentially starting from the side of the radial transmission line 19 in the direction of the side of the coaxial transmission line 21. The radius profiles of the radii and/or inner radii of the cross-sectional areas of the first and second spatial material extents are produced in a manner running parallel to one another starting from the side of the radial transmission line 19 in the direction of the side of the coaxial transmission line 21.

The solid intermediate piece 23 has, for example, the form of a solid funnel, couples the radial transmission line to the coaxial transmission line and may likewise be referred to as a taper. The intermediate piece 23 may likewise be produced in a design which is not solid, for example in the form of a funnel having a through-opening or a hole. In a particularly advantageous manner, the characteristic impedances of the radial transmission line and of the coaxial transmission line are matched to one another. A first characteristic impedance of a radial line can be described using equation

$${Z}_{Radial} = {Z}_{0} \cdot \frac{{G}_{0} ( k r )}{{G}_{1} ( k r )} \qquad ( 1 )$$

In this case, k is the wave number vector, Z0 is the field characteristic impedance with a magnitude of 377Ω and

G0(kr), G1(kr) are functions which are defined in a similar manner to Hanke and by Holland.

A second characteristic impedance of a coaxial line can be described, for example, by the following equation

$${Z}_{Radial} = {Z}_{0} \cdot \frac{{Z}_{0}}{2 π \sqrt{{ɛ}_{r}}} ln ( \frac{{R}_{2}}{{R}_{1}} ) \qquad ( 2 )$$

In this case, R1 is the inner radius of the coaxial line, R2 is the outer radius of the coaxial line and Z0 is the field characteristic impedance with a magnitude of 377Ω. R1 is likewise the radius of the inner conductor 25. R2 is likewise the inner radius of the outer conductor 27. An influence of the characteristic impedance can be discerned using these equations (1) and (2). A connection of the radial transmission line 19 to the coaxial transmission line 21 in the form of a funnel-shaped structure is intended to be used to match both characteristic impedances to one another. This enables reflection-free feeding from the radial transmission line 19 into the coaxial transmission line 21 and into the coaxial structure of the IVA.

FIG. 6 shows a temporal profile of a reflected signal R and of a transmitted signal T in the time domain when using a first stage of an IVA. This simulation shows reflections R, caused by an approximation, of less than 2%. The radial transmission line 19 and the coaxial transmission line 21 may likewise be matched using exponential functions which connect the two lines to one another. Such exponential functions must have the property whereby the structures continuously merge into one another.

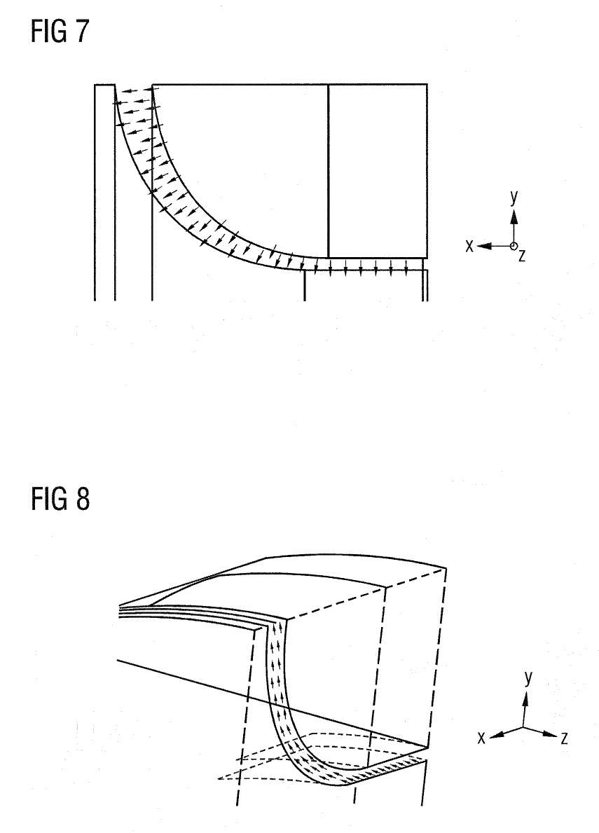

FIG. 7 shows an illustration of the profile of the electrical fields in a first stage of an IVA. Arrows represent a vector field.

FIG. 8 shows an illustration of magnetic fields in a first stage of an IVA. Arrows represent a vector field.

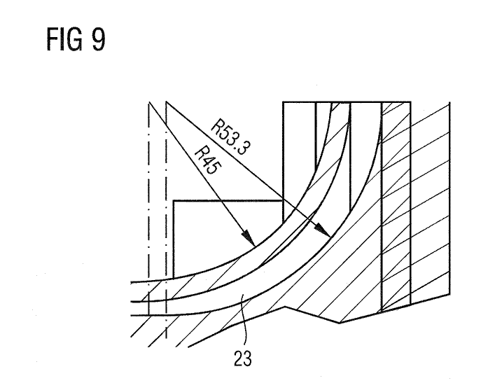

FIG. 9 shows a further view of a funnel-shaped intermediate piece 23. In this case, this intermediate piece 23 or taper is matched to the different conductor structures by selecting different inner and outer radii from the radial transmission line 19 to the coaxial transmission line 21. FIG. 9 shows, for example, an outer radius R of the outer conductor 27 with a magnitude of 53.5 and a radius R1 of the inner conductor 25 with a magnitude of R=45. FIG. 9 shows matching of the radial transmission line 19 and of the coaxial transmission line 21 which are connected by the funnel-shaped intermediate piece 23, the inner and outer radii of which vary along the connection. In practice, it is sufficient to connect the radial transmission line 19 and the coaxial transmission line 21 with two different radii.

An apparatus and a method for generating high-voltage pulses, in particular by an inductive voltage adder IVA, is described in which an electromagnetically coupling, funnel-shaped intermediate piece 23 is positioned between a radial transmission line 19 and the coaxial transmission line 21 in the first stage 17 for the purpose of transmitting electromagnetic waves from the radial transmission line 19 to the coaxial transmission line 21.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-24. (canceled)

25. An apparatus for generating high-voltage pulses, comprising:
a series circuit of discrete stages of voltage sources which are arranged along a wave propagation main axis, each of the discrete stages having a radial transmission line having a first characteristic impedance and a coaxial transmission line having a second characteristic impedance, electromagnetic fields of the series circuit combining during pulse generation, and waves propagating in each of the discrete stages along the radial transmission line into the coaxial transmission line; and
a first stage of the discrete stages having a steady and continuous transition region from a first stage radial transmission line to a first stage coaxial transmission line, a continuous transition from a first characteristic impedance of the first stage to a second characteristic impedance of the first stage formed in the steady and continuous transition region.

26. The apparatus as claimed in claim 25, wherein the steady and continuous transition region in the first stage is configured based on the first characteristic impedance of the first stage radial transmission line, inner and outer radii of the first stage coaxial transmission line, and a field characteristic impedance.

27. The apparatus as claimed in claim 25, wherein, in the steady and continuous transition region of the first stage, walls of the first stage radial transmission line extending transversely with respect to the wave propagation main axis continuously merge into walls of the first stage coaxial transmission line extending longitudinally with respect to the wave propagation main axis along winding profiles in a rotationally symmetrical manner with respect to the wave propagation main axis.

28. The apparatus as claimed in claim 27, wherein the steady and continuous transition region of the first stage has a first spatial material extent with circular cross-sectional areas perpendicular to the wave propagation main axis, circular cross-sectional areas having radii continuously smaller from a first outer radius of an outer conductor to a second outer radius of an inner conductor of the coaxial transmission line along the wave propagation main axis in a wave propagation direction.

29. The apparatus as claimed in claim 28, wherein the radii of the circular cross-sectional areas of the first spatial material extent are exponentially smaller from the radial transmission line towards the coaxial transmission line.

30. The apparatus as claimed in claim 28, wherein the first spatial material extent is a separate intermediate piece.

31. The apparatus as claimed in claim 30, wherein the first spatial material extent includes a material selected from the group consisting of copper, steel and aluminum.

32. The apparatus as claimed in claim 27, wherein the steady and continuous transition region of the first stage has a second spatial material extent with circular cross-sectional areas perpendicular to the wave propagation main axis, the circular cross-sectional areas having a constant outer radius and inner radii continuously smaller from an outer radius of the outer conductor of the first stage coaxial transmission line to an inner radius of the outer conductor of the first stage coaxial transmission line along the wave propagation main axis in a wave propagation direction.

33. The apparatus as claimed in claim 32, wherein the inner radii of the cross-sectional areas of the second spatial material extent are exponentially smaller from the radial transmission line towards the coaxial transmission line.

34. The apparatus as claimed in claim 32, wherein radius profiles of first radii of the cross-sectional areas of the first spatial material extent and of the inner radii of the cross-sectional areas of the second spatial material extent are parallel from the radial transmission line towards the coaxial transmission line.

35. The apparatus as claimed in claim 34, wherein an intermediate piece has an outer surface profile of a tapering funnel along and in the wave propagation direction.

36. The apparatus as claimed in claim 32, wherein the second spatial material extent includes a material selected from the group consisting of copper, steel and aluminum.

37. The apparatus as claimed in claim 25, wherein all of the discrete stages have a same modular structure.

38. The apparatus as claimed in claim 25, wherein the apparatus is an inductive voltage adder.

39. A method for generating high-voltage pulses in an inductive voltage adder, comprising:
combining electromagnetic fields during pulse generation of a series circuit of discrete stages of voltage sources arranged along a wave propagation main axis;
propagating waves along a radial transmission line having a first characteristic impedance into a coaxial transmission line having a second characteristic impedance in each of the discrete stages along the radial transmission line into the coaxial transmission line; and
forming a continuous transition in a first stage of the discrete stages from a first characteristic impedance to a second characteristic impedance using a steady and continuous transition region from a radial transmission line to a coaxial transmission line.

40. The method as claimed in claim 39, wherein, in the steady and continuous transition region of the first stage, walls of the radial transmission line extending transversely with respect to the wave propagation main axis continuously merge into walls of the coaxial transmission line extending longitudinally with respect to the wave propagation main axis along winding profiles in a rotationally symmetrical manner with respect to the wave propagation main axis.

41. The method as claimed in claim 39, wherein the steady and continuous transition region in the first stage is configured based on the first characteristic impedance of the radial transmission line, inner and outer radii of the coaxial transmission line, and a field characteristic impedance.

42. The method as claimed in claim 41, wherein the steady and continuous transition region of the first stage has a first spatial material extent with circular cross-sectional areas perpendicular to the wave propagation main axis, circular cross-sectional areas having radii continuously smaller from a first outer radius of an outer conductor to a second outer radius of an inner conductor of the coaxial transmission line along the wave propagation main axis in a wave propagation direction.

43. The method as claimed in claim 42, wherein the radii of the circular cross-sectional areas of the first spatial material extent are exponentially smaller from the radial transmission line towards the coaxial transmission line.

44. The method as claimed in claim 42, wherein the first spatial material extent is a separate intermediate piece.

45. The method as claimed in claim 44, wherein the first spatial material extent includes a material selected from the group consisting of copper, steel and aluminum.

46. The method as claimed in claim 41, wherein the steady and continuous transition region of the first stage has a second spatial material extent with circular cross-sectional areas perpendicular to the wave propagation main axis, the circular cross-sectional areas having a constant outer radius and inner radii continuously smaller from an outer radius of the outer conductor of the coaxial transmission line to an inner radius of the outer conductor of the coaxial transmission line along the wave propagation main axis in a wave propagation direction.

47. The method as claimed in claim 46, wherein the inner radii of the cross-sectional areas of the second spatial material extent are exponentially smaller from the radial transmission line towards the coaxial transmission line.

48. The method as claimed in claim 46, wherein radius profiles of first radii of the cross-sectional areas of the first spatial material extent and of the inner radii of the cross-sectional areas of the second spatial material extent are parallel from the radial transmission line towards the coaxial transmission line.

49. The method as claimed in claim 48, wherein an intermediate piece has an outer surface profile of a tapering funnel along and in the wave propagation direction.

50. The method as claimed in claim 46, wherein the second spatial material extent includes a material selected from the group consisting of copper, steel and aluminum.

51. The method as claimed in claim 39, wherein all of the discrete stages have a same modular structure.
